(19) United States
(12) Patent Application Publication
(10) Pub. No.: US 2010/0046174 A1
(43) Pub. Date: Feb. 25, 2010

(54) PRINTED CIRCUIT BOARD FIXING STRUCTURE AND ELECTRONIC DEVICE WITH SAME

(75) Inventor: BAO-SHUAI LIU, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO.,LTD., Shenzhen City (CN); HON HAI PRECISION INDUSTRY CO.,LTD., Tu-Cheng (TW)

(21) Appl. No.: 12/340,760

(22) Filed: Dec. 22, 2008

(30) Foreign Application Priority Data
Aug. 20, 2008 (CN) 200810304078.7

(51) Int. Cl. H05K 1/11; H05K 5/00

(52) U.S. Cl. 361/724; 361/784

(57) ABSTRACT

An electronic device includes chassis, a first printed circuit board, a second printed circuit board and a shell. The chassis includes a locating surface on which the first printed circuit board is mounted. The second printed circuit board is substantially perpendicularly mounted on the first circuit board and electrically coupled it. The shell is positioned on the locating surface to cover and receive the first and second printed circuit boards.

### BACKGROUND

1. Technical Field

The present invention relates to electronic devices, and particularly, to a printed circuit board fixing structure.

2. Description of the Related Art

Printed circuit board (PCB) are widely used in various electronic devices for mechanically supporting and electrically connecting electronic components. As the functionality of electronic devices increasing, printed circuit board has to be designed larger and larger for supporting more and more electronic components thereon to implement more functionality. Accordingly, an electronic device must be designed large enough to accommodate bigger printed circuit board. However, this increase in size is incompatible with the tendency of miniaturization of electronic devices. To reduce the profile size of the PCB fixing structure, the printed circuit board is divided depending on functions of the printed circuit board, into two or more isolated sub-circuit boards smaller than the original PCB. Those sub-circuit boards generally are overlapped or stacked together to form a multilayer PCB fixing structure 200 as shown in FIG. 3. In the PCB fixing structure 200, a top sub-circuit board 210 is stacked over a bottom sub-circuit board 220 via a support 230, and a number of electronic elements 240 are respectively mounted on the upper surface 222 of the bottom sub-circuit board 220 and the lower surface 212 of the top sub-circuit board 210. The top and bottom sub-circuit board 210, 220 are electrically connected each other by a cable 250. Through this configuration, the PCB fixing structure 200 can be effectively downsized. However, the defective sub-circuit boards are difficult to repair, because the faulty sub-circuit boards need to be detached from the stacked sub-circuit boards, repaired, and then assembled with the others again. The processes of repairing defective sub-circuit boards are time-consuming and cumbersome. In addition, because of layout and the position of the support 230, air circulation in the PCB fixing structure 200 is poor. Therefore, the work-life of an electronic device using the above configuration of sub-circuit boards may be reduced.

Therefore, it is desired to design a PCB fixing structure and an electronic device with the same to overcome the above described problems.

### BRIEF DESCRIPTION OF THE DRAWINGS

FIG. 1 is a schematic exploded view of an electronic device including a PCB fixing structure according to an exemplary embodiment.

FIG. 2 is a schematic cross-sectional view of the electronic device of FIG. 1.

FIG. 3 is a PCB fixing structure according to related art.

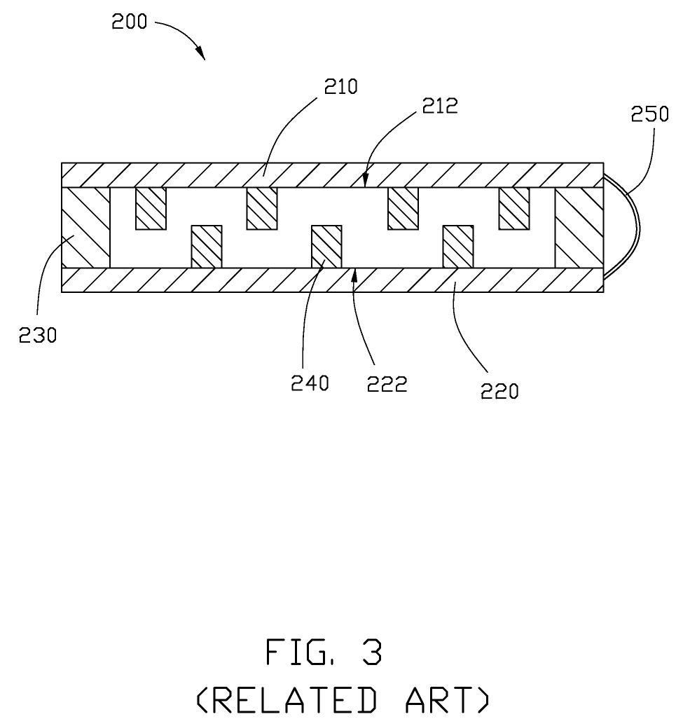

### DETAILED DESCRIPTION OF THE PREFERRED EMBODIMENTS

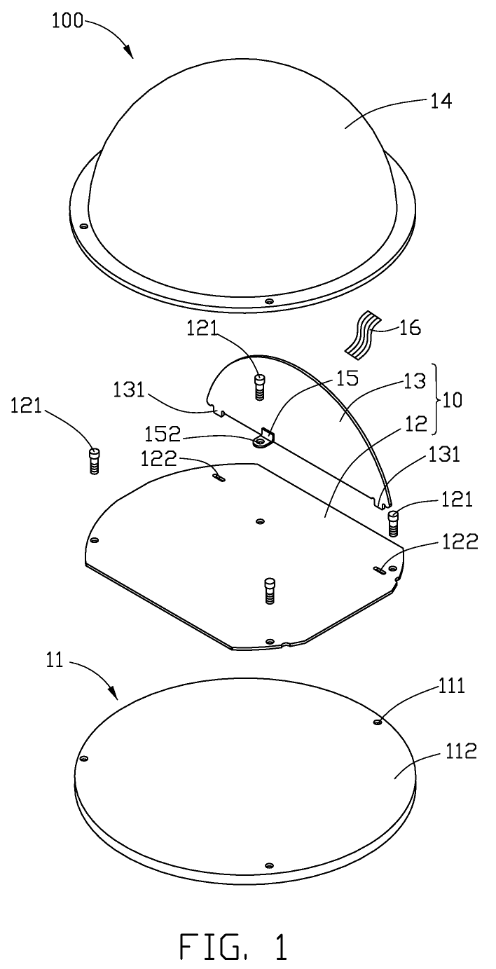

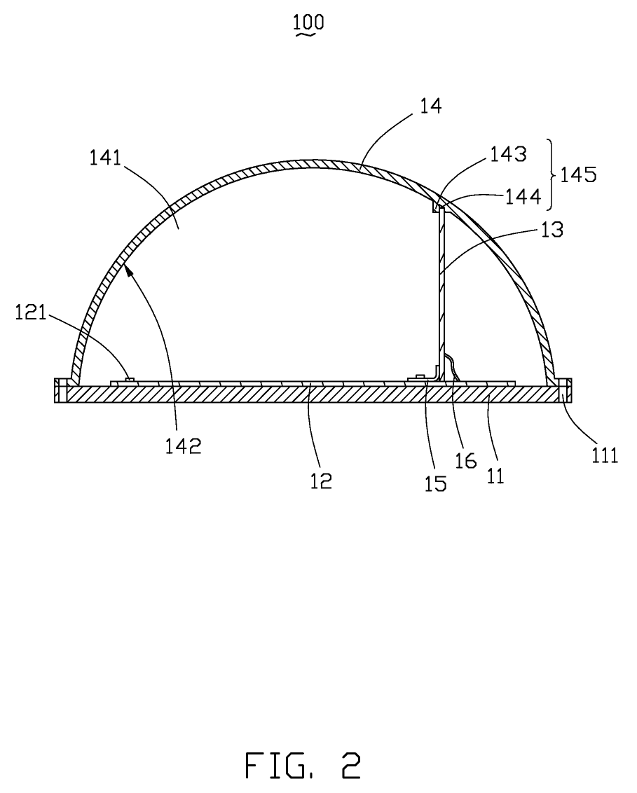

Referring to FIG. 1 and 2, an electronic device 100 is shown.

The electronic device 100 includes a chassis 11, a shell 14 defining a receiving room 141, a printed circuit board (PCB) fixing structure 10, and a number of functioning components (not shown), including electronic elements and mechanical structures and so on used for implementing various functions of the electronic device 100, mounted on the PCB fixing structure 10. The chassis 11 includes a locating surface 112 on which the shell 14 is mounted, and the receiving room 141 of the shell 14 is sealed by the chassis 11 to form a closed space for receiving the PCB fixing structure 10 and those functioning components.

The chassis 11 of the electronic device 100 is configured for supporting and fixing the PCB fixing structure 10. A number of threaded holes 111 are defined on the locating surface 112 of the chassis 11 for threadedly connecting with corresponding number of bolts 121 to fix the PCB fixing structure 10 and the shell 14. Alternatively, welding or other affixing method can also be used to fix the PCB fixing structure 10 and the shell 14 onto the chassis 11.

The shell 14 is mounted on the locating surface 112 of the chassis 11 for covering and protecting the PCB fixing structure 10 and the electronic components of the electronic device.

The PCB fixing structure 10 is mounted on the locating surface 112 of the chassis 11 and received in the receiving room 141 of the shell 14 for mechanically supporting and electrically connecting those electronic components of the electronic device 100. The PCB fixing structure 10 includes a first printed circuit board 12 and at least one second printed circuit board 13 fixed on the first printed circuit board 12.

The first printed circuit board 12 of the PCB fixing structure is mounted on the locating surface 112 of the chassis 11 via the bolts 121. The first printed circuit board 12 defines at least one slot 122 for the insertion of the second printed circuit board 13 thereby to fix the second printed circuit board 13.

The second printed circuit board 13, such as an expansion card with some complementary functions, is substantially perpendicularly attached on the first printed circuit board 12. The second printed circuit board 13 includes at least one plugging portion 131 protruding outward from an edge corresponding to the slot 122 of the first printed circuit board 12. The second printed circuit board 13 is semicircle shaped. Correspondingly, the shell 14 of the electronic device 100 can be designed as hemispherical according to the profile of the second printed circuit board 13, so that the shell 14 can be designed smaller and more compact. The second printed circuit board 13 is substantially perpendicularly mounted on the first printed circuit board 12 by inserting the plugging portion 131 into the slot 122 of the first printed circuit board 12. Thus enough space is defined between the first and second printed circuit boards 12, 13 for quickly dispersing the heat produced by those electronic components installed on the first and second printed circuit boards 12, 13. In addition, the first and second printed circuit boards 12 and 13 can be easily repaired and replaced without any cumbersome/tedious procedures due to the spacious connecting relationship. In present invention the first and second printed circuit boards 12, 13 are electrically connected to each other by the cable/flexible circuit board 16. However, other technologies or standards can be used to connect the first printed circuit board 12 to the second printed circuit board 13 such as the peripheral component interface (PCI) standard. Understandably, if more than one second printed circuit board 13 needs to be installed on the first printed circuit board 12, the more than one second printed circuit boards 13 can be substantially perpendicularly mounted on the first printed circuit board 12 and spaced from each other so that each second printed circuit board 13 can be repaired and replaced easily.

To firmly fix the second printed circuit board 13, an auxiliary fixing structure 145 is formed on the shell 14. The fixing structure 145 includes a flange 143 formed on the inner surface 142 of the shell 14 corresponding to the second printed circuit board 13, and a channel 144 defined on the flange 143 for a corresponding edge of the second printed circuit board 13 to be plugged into. The second printed board 13 is firmly held by the fixing structure 145 which receives an edge of the second printed board 13 in the channel 144. Thus, the second printed circuit board 13 can be firmly fixed between the first printed circuit board 13 and the shell 14. Understandably, if more than one second printed circuit boards 13 mounted on the first printed circuit board 12, a corresponding number of the flanges 143 and channels 144 should be arranged on the inner surface 142 of the shell 14 for receiving the edges of the corresponding second printed circuit board 13 and fixing them.

For enhancing the connecting stability of the first printed circuit board 12 and the second printed circuit board 13, at least one supporting device 15 having two perpendicularly connecting arms is employed to connect the first printed circuit board 12 and the second printed circuit board 13 together, and each arm can be defined a screw holes 152 thereon for a bolt or a screw screwing therein to fix the supporting device on each board. The boards are connected by mounting the arms of the corner connecting device 15 to the adjacent first and second printed circuit boards 12, 13, correspondingly and the arms are attached to the boards via mechanical connecting means such as screws, bolt and nut, or other fixing elements.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A printed circuit board (PCB) fixing structure, comprising:
a first printed circuit board, and
at least one second printed circuit board perpendicularly mounted on the first circuit board and electrically coupled it.

2. The PCB fixing structure as claimed in claim 1, wherein at least one slot is defined on the first printed circuit board, and a corresponding plugging portion is formed on an edge of the second printed circuit board for inserting in the corresponding slot to fix the first and second printed circuit boards together.

3. The PCB fixing structure as claimed in claim 1 further comprising a corner connecting device having two corner connected arms respectively mounted on the first and second adjacent printed circuit board.

4. An electronic device, comprising:
a chassis having a locating surface;
a first printed circuit board(PCB) mounted on the locating surface of the chassis;
at least one second printed circuit board perpendicularly mounted on the first circuit board and electrically coupled with it; and
a shell positioned on the locating surface to cover and receive the first and second printed circuit boards therein.

5. The electronic device as claimed in claim 4, wherein at least one slot is defined on the first printed circuit board, and a corresponding plugging portion formed on an edge of the second printed circuit board is inserted in the corresponding slot to fix the second printed circuit board on the first printed circuit.

6. The electronic device as claimed in claim 4, wherein the PCB fix structure further comprises a corner connecting device having two corner connected arms respectively mounted on the first and second adjacent printed circuit board.

7. The electronic device as claimed in claim 4, wherein a fixing structure is formed on the shell, and one edge of the second printed circuit board 13 is fixed on the fixing structure.

8. The electronic device as claimed in claim 4, wherein the fixing structure comprises a flange formed on the inner surface of the shell corresponding to the second printed circuit board, and a channel defined on the flange for receiving one edge of the second printed circuit board therein.

9. The electronic device as claimed in claim 4, wherein the second printed circuit board is substantially semicircle shaped.

10. The electronic device as claimed in claim 8, wherein the shell is a substantially hollow hemispherical body matching with the shape of the second printed circuit board.

11. An electronic device, comprising:
a chassis;
a first printed circuit board mounted on the chassis;
at least one second printed circuit board crosswise mounted on the first printed circuit board and electrically coupled with it; and
a hollow shell positioned on the chassis and receiving the first printed circuit board and the at least one second printed circuit board therein, the hollow shell comprising a flange protruded from the inner surface thereof for fixing an edge of the second printed circuit boar.

12. The electronic device as claimed in claim 11, wherein at least one slot is defined on the first printed circuit board, and a corresponding plugging portion is formed on an edge of the second printed circuit board for inserting in the corresponding slot to fix the first and second printed circuit boards together.

13. The electronic device as claimed in claim 11, further comprising a corner connecting device having two corner connected arms, respectively mounted on the first and second adjacent printed circuit board.

14. The electronic device as claimed in claim 11, wherein a channel is defined on the flange for holding the second printed circuit board via receiving an edge of the second printed circuit board therein.

15. The electronic device as claimed in claim 11, wherein the second printed circuit board is semicircle shaped.

16. The electronic device as claimed in claim 15, wherein the shell is shaped as a substantially hollow hemispherical body matching with the shape of the second printed circuit board.
